(19) United States
(12) Patent Application Publication
(10) Pub. No.: US 2006/0187506 A1
(43) Pub. Date: Aug. 24, 2006

(54) Color image processing apparatus and color image processing method

(75) Inventor: Katsushi Minamino, Kyoto-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Murata Kikai Kabushiki Kaisha, Kyoto-shi (JP)

(21) Appl. No.: 11/355,991

(22) Filed: Feb. 17, 2006

(30) Foreign Application Priority Data
Feb. 23, 2005 (JP) 2005-046532

(51) Int. Cl. G03F 3/08

(52) U.S. Cl. 358/518

(57) ABSTRACT

A color adjustment, which matches a directional property STUV given by sensuous terms relating to color tones, can be performed by converting color image data into a color space having a direction of lightness M, a direction of saturation N and a hue axis K, and relatively changing a lightness component and a saturation component of the color image data in the color space.

### BACKGROUND OF THE INVENTION

1. Field of the Invention

The present invention relates to a color image processing apparatus for performing color adjustment on color image data.

2. Description of Related Art

Some digital color complex machines include a color adjusting function for adjusting color of read color image data. A color adjustment is performed by converting image data read by a scanner or the like into an expression by a uniform color space, for example, a color space of Lab, which defines color by digitalizing three attributes of color, that is, “hue”, “lightness” and “saturation”, and then changing a lightness component in this color space by a “lightness adjusting function”, and changing a saturation component in the color space by a “saturation adjusting function”. For example, when the lightness component of image data is increased by this “lightness adjusting function”, image data with high “lightness” can be obtained while storing its “hue” and “saturation”.

The uniform color space represents a space created so that an equal distance in a space corresponds to a perceptual difference. In other words, the uniform color space is a space which has a proportional relation between a degree of difference that human being senses for two different colors and a distance between two points plotted in the color space.

In such a uniform color space, the three attributes of color can be treated independently. This independency is utilized in a technique for creating a monochrome image in which color properties of color images are utilized.

Sensuous terms relating to color conditions include “bright”, “dark”, “deep” and “pale”. Directional properties of these sensuous terms (daily words for expressing color sense) do not match the respective elements; “hue”, “lightness” and “saturation” which are defined in the uniform color space. For example, a sensuous term “bright” does not match a directional property that the lightness component is large in the color space. Therefore, even when the lightness component in the image data is increased by the “lightness adjusting function” in order to obtain a “brighter” image, there is a possibility that an expected image cannot be obtained.

In other words, the sensuous terms relating to color tones which are generally used indicate a directional property that “lightness”, “saturation” and “hue” are changed in combination. Therefore, for example, in order to adjust the color to obtain a “brighter” color image, it is necessary to change the lightness component and the saturation component of the image data adequately while using the “lightness adjusting function” and the “saturation adjusting function” in combination. It is also applied to a case of a color adjustment which matches the sensuous terms such as “dark”, “deep” and “pale”.

The color adjustment for controlling the lightness component and the saturation component in combination in this manner is enabled only when one has a full knowledge about the directional property of the lightness or the saturation defined by the color space, and hence it is not easy for general users.

In case of a monochrome complex machine, the terms “dark” and “deep” have almost the same meaning, and hence it is not necessary to differentiate these terms. However, in case of a color, these two terms have different meanings from one another. Therefore, in case of a color image, a color adjustment by the sensuous terms is not achieved simply by performing an adjustment to be performed for a monochrome image for a plurality of color components individually, and it would be very complicated with the respective elements of the color intertwined with each other.

### SUMMARY OF THE INVENTION

In order to overcome the problems described above, an advantage of the invention is to provide a color image processing apparatus that enables an easy color adjustment which matches sensuous terms relating to color tones.

According to an aspect of the present invention, a color image processing apparatus for executing a color adjustment on color image data includes an operation input unit and a color adjusting unit. The operation input unit instructs to increase or decrease a property expressed by a predetermined sensuous term relating to a color tone of the color image data. The color adjusting unit changes the color image data in a direction of change corresponding to the predetermined sensuous term in a predetermined color space in response to the instruction about the increase or decrease, thereby executing the color adjustment of the color image data. The direction of change is a direction which relatively changes at least two components of a lightness component, a saturation component and a hue component of the color image data in the color space.

According to another aspect of the present invention, the color image processing apparatus includes a plurality of modes, in which a plurality of terms are defined different from each other as the sensuous terms, for causing the respective color image data to be changed in a plurality of directions different from each other in the color space as the directions of change corresponding to the plurality of terms. The color adjusting unit performs the color adjustment in a mode selected by the operation input unit from the plurality of modes.

According to another aspect of the present invention, the color image processing apparatus further includes a prohibiting unit for prohibiting duplicated inputs of instructions about the change of the color image data in the plurality of directions from the operation input unit.

According to another aspect of the present invention, the prohibiting unit includes a compulsively canceling unit which, in case when an instruction on the change of the color image data in one direction out of the plurality of directions is given from the operation input unit and then an instruction on the change of the color image data in another direction out of the plurality of directions is given from the operation input unit, compulsively cancels the instruction of the color adjustment which has already given for the color image data in one direction.

According to another aspect of the present invention, the directions of change include two different directions for relatively changing a lightness component and a saturation component in the color space.

According to another aspect of the present invention, the color adjusting unit includes a “brightness” adjusting mode coordinated with the change in “brightness” as the sensuous term for causing the lightness component and the saturation component of the color image data to be relatively changed with the same positive or negative sign in response to an input of the instruction from the operation input unit.

According to another aspect of the present invention, the color adjusting unit includes a “deepness” adjusting mode coordinated with the change in “deepness” as the sensuous term for causing the lightness component and the saturation component of the color image data to be relatively changed with the same positive or negative sign in response to an input of the instruction from the operation input unit.

According to another aspect of the present invention, the plurality of terms include a plurality of terms which signify the opposite meaning in pairs.

According to another aspect of the present invention, the color adjusting unit includes a first color adjusting mode, a second color adjusting mode, a third color adjusting mode and a fourth color adjusting mode. The first color adjusting mode is a mode for increasing the lightness component and increasing the saturation component. The second color adjusting mode is a mode for decreasing the lightness component and decreasing the saturation component. The third color adjusting mode is a mode for decreasing the lightness component and increasing the saturation component. The fourth color adjusting mode is a mode for increasing the lightness component and decreasing the saturation component. A relative change between the lightness component and the saturation component in the first color adjusting mode has a directional property that matches a sense given by the term “brighter” as the sensuous term. The relative change between the lightness component and the saturation component in the second color adjusting mode has a directional property that matches a sense given by the term “darker” as the sensuous term. The relative change between the lightness component and the saturation component in the third color adjusting mode has a directional property that matches a sense given by the term “deeper” as the sensuous term. The relative change between the lightness component and the saturation component in the fourth color adjusting mode has a directional property that matches a sense given by the term “paler” as the sensuous term.

According to another aspect of the present invention, the color adjusting unit includes a first color adjusting mode and a second color adjusting mode. The first color adjusting mode is a mode for relatively increasing and decreasing the lightness component and the saturation component in the same direction. The second color adjusting mode is a mode for relatively increasing and decreasing the lightness component and the saturation component in opposite directions. The relative change between the lightness component and the saturation component in the first color adjusting mode has a directional property that matches a sense given by the term “brighter” as the sensuous term. The relative change between the lightness component and the saturation component in the second color adjusting mode has a directional property that matches a sense given by the term “deeper” as the sensuous term.

According to another aspect of the present invention, a color image processing method for executing a color adjustment on color image data includes an operation input step and a color adjusting step. The operation input step gives an instruction on increase or decrease of a property expressed by a predetermined sensuous term relating to a color tone of the color image data. The color adjusting step changes the color image data in the direction corresponding to the predetermined sensuous term in a predetermined color space in response to the instruction about the increase or decrease, thereby executing the color adjustment of the color image data. The direction of change is a direction which relatively changes at least two components out of a lightness component, a saturation component and a hue component of the color image data in the color space.

According to the present invention, since at least two of the lightness component, the saturation component and the hue component of the color image data in the color space are changed based on the relative relation having a directional property that matches the sense given by the sensuous term relating to the color tone, the color adjustment that matches the sensuous term relating to the color tone can easily be performed.

Since the present invention includes the modes corresponding respectively to the plurality of sensuous terms, and the color adjustment can be performed independently in the mode selected therefrom, a wide range of color adjustment which cannot be achieved by the color adjustment corresponding only to one term is enabled, and an interference among the plurality of modes can be prevented.

In the present invention, since a duplicated selection of the plurality of modes is prohibited, the user is prevented from selecting the plurality of modes in a duplicated manner erroneously. Therefore, the adjustment result which is not desired by the user due to mutual interference of the color adjustments in the plurality of modes can be prevented.

In the present invention, when the user attempts to specify the plurality of modes, the previously specified mode is compulsively cancelled. Therefore, even when the user does not make an operation to intentionally avoid the duplicated selection, the duplicated selection can be prevented automatically.

In the present invention, the color adjusting mode expressed by the sensuous terms relating to the lightness and the saturation which are often specified by the user can be selected, and hence a frequency of usage of this color adjusting mode can be increased.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a block diagram illustrating a structure of a digital color complex machine;

FIG. 2 is a flowchart illustrating an image processing operation executed by an input image processing unit and an output image processing unit;

FIG. 3 is a drawing illustrating a Lab color space;

FIG. 4 is a drawing illustrating a plan in the Lab color space;

FIG. 5 is a drawing illustrating an operating unit according to a first preferred embodiment of the present invention;

FIG. 6 is a drawing illustrating an example of an adjustment coefficient table according to the first preferred embodiment of the present invention;

FIG. 7 is a drawing illustrating the plan in the Lab color space;

FIG. 8 is a drawing illustrating another example of the adjustment coefficient table according to the first preferred embodiment of the present invention;

FIG. 9 is a flowchart illustrating a color adjustment operation of a color adjustment unit;

FIG. 10 is a drawing illustrating the plan in the Lab color space;

FIG. 11 is a drawing illustrating the operating unit according to a second preferred embodiment of the present invention; and

FIG. 12 is a drawing illustrating an example of an adjustment coefficient table according to the second preferred embodiment of the present invention.

### DETAILED DESCRIPTION OF PREFERRED EMBODIMENTS

### 1. Digital Color Complex Machine 100

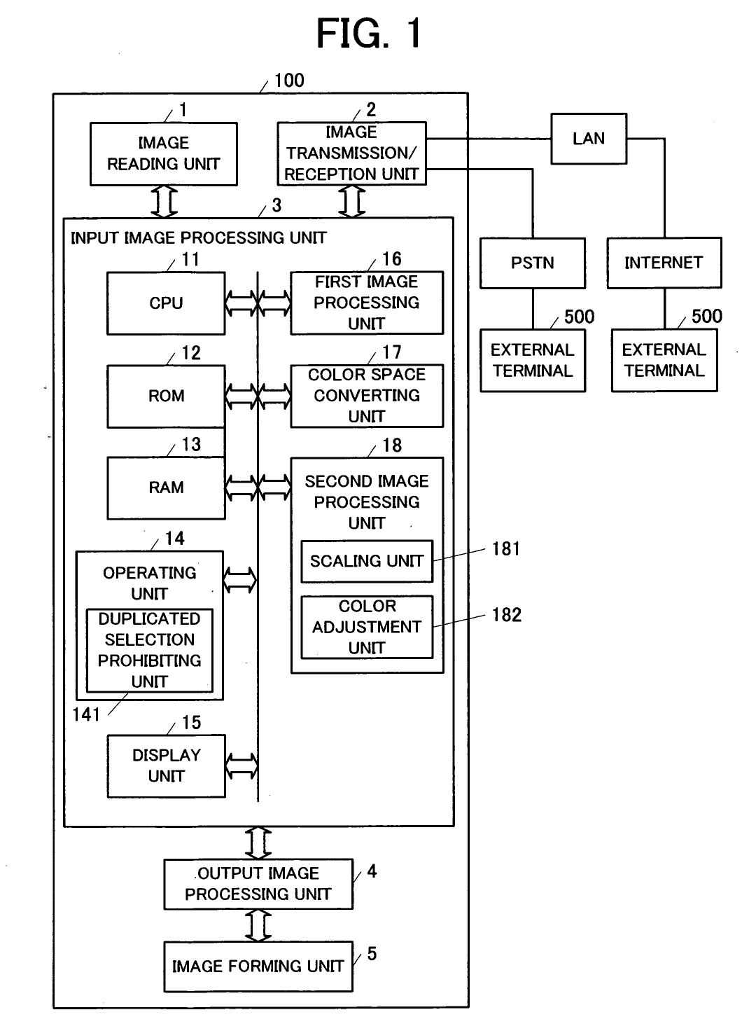

FIG. 1 is a block diagram illustrating a structure of a digital color complex machine 100 in which a function corresponding to a color image processing apparatus as a preferred embodiment of the present invention is built in. The digital color complex machine 100 is a complex machine having a color facsimile function and a color copying function. The digital color complex machine 100 includes an image reading unit 1, an image transmission/reception unit 2, an input image processing unit 3, an output image processing unit 4 and an image forming unit 5. The input image processing unit 3 and the output image processing unit 4 carry out various image processing. The respective functional units are connected to each other with internal communication unit such as a bus.

The image transmission/reception unit 2 includes a Network Control Unit (NCU), not illustrated, which is capable of carrying out facsimile communication with an external terminal 500 via a Public Switched Telephone Network (PSTN), and a Local Area Network Interface (LAN I/F), not illustrated, which is capable of carrying out Internet facsimile communication with the external terminal 500 via a LAN or the Internet.

Digital image data of an image as a manuscript can be obtained by following two methods. A first method is a method of obtaining original image data from the image reading unit 1. For example, in the image reading unit 1, reading of the original image is performed pixel by pixel by a full-color flat bed scanner. Accordingly, the image data of the original image is obtained by respective color components of Red, Green and Blue (RGB). The image data of the original image obtained here, more specifically, RGB signals corresponding to the respective pixels outputted from a Charge-Coupled Device (CCD) of the flat bed scanner, are refereed to as RGB image data, hereinafter.

A second method is a method of receiving the original image data by the image transmission/reception unit 2. The image transmission/reception unit 2 acquires image data of the original image by an electronic mail communication from the external terminal 500 connected, for example, via the Internet. The image data obtained here is compressed in, for example, the Joint Photographic Experts Group (JPEG) format, and a color expression of the image data is of a color system having a Ycc color space (hereinafter, referred to as Ycc image data).

After the input image processing unit 3 and the output image processing unit 4 executes various image processing on the image data (RGB image data or Ycc image data) of the original image acquired by the image reading unit 1 or the image transmission/reception unit 2, the image forming unit 5 prints the image data onto a printing medium such as paper by, for example, a full color electrophotographic system.

In the following, a description will be made of a case in which the image data of the original image acquired from an input device is specifically the RGB image data. When the image data of the original image is the Ycc image data, the description will be applicable to such a case by replacing a Lab color space with the Ycc color space.

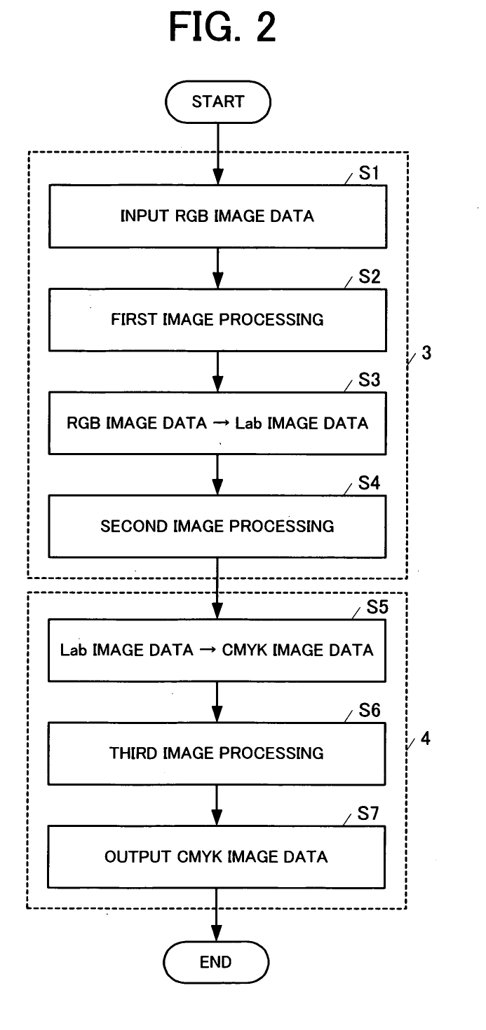

Subsequently, taking a case in which the color copying function of the digital color complex machine 100 is used as an example, the image processing executed by the input image processing unit 3 and the output image processing unit 4 will be described in further detail. FIG. 2 is a flowchart illustrating an image processing operation executed by the input image processing unit 3 and the output image processing unit 4.

When the RGB image data is supplied to the input image processing unit 3 from the image reading unit 1 (step S1), a first image processing is executed on the RGB image data (step S2). The first image processing is a predetermined correction process for the RGB signals such as a shading correction or a γ correction.

Subsequently, the RGB image data is converted from an expression by an RGB color space to an expression by a predetermined color space by a matrix calculation or the like (step S3). The predetermined color space is, for example, a color space such as Lab or Ycc having one achromatic axis in a three-dimensional space. In this preferred embodiment, it is assumed that the RGB image data is converted to the expression by the Lab color space (hereinafter, referred to as Lab image data). An execution by the Ycc color space and so on is also possible.

Subsequently, a second image processing is executed on the Lab image data (step S4). The second image processing is mainly a scaling or a color adjustment. The scaling or the color adjustment is to be performed in response to an instruction from the user. When there is no instruction from the user, such image processing is not executed. The processings from step S1 to step S4 are executed by the input image processing unit 3, and the subsequent processings from step S5 to step S7 are executed by the output image processing unit 4, respectively.

When the Lab image data, on which the second image processing has been executed, is supplied from the input image processing unit 3 to the output image processing unit 4, the Lab image data is converted to digital signals of the respective color components; Cyan (C), Magenta (M), Yellow (Y) and blacK (K) (hereinafter referred to as CMYK image data) using a three-dimensional lookup table and an interpolating calculation (step S5).

Subsequently, a third image processing is executed on the CMYK image data (step S6). The third image processing includes binarizing for each color component C, M, Y, K using a dither method, an error diffusion method or the like. The CMYK image data, on which the third image processing has been executed, is outputted to a CMYK image forming engine in the image forming unit 5, respectively (step S7). The outline of the operation of the digital color complex machine 100 is as described thus far.

### 2. Lab Color Space

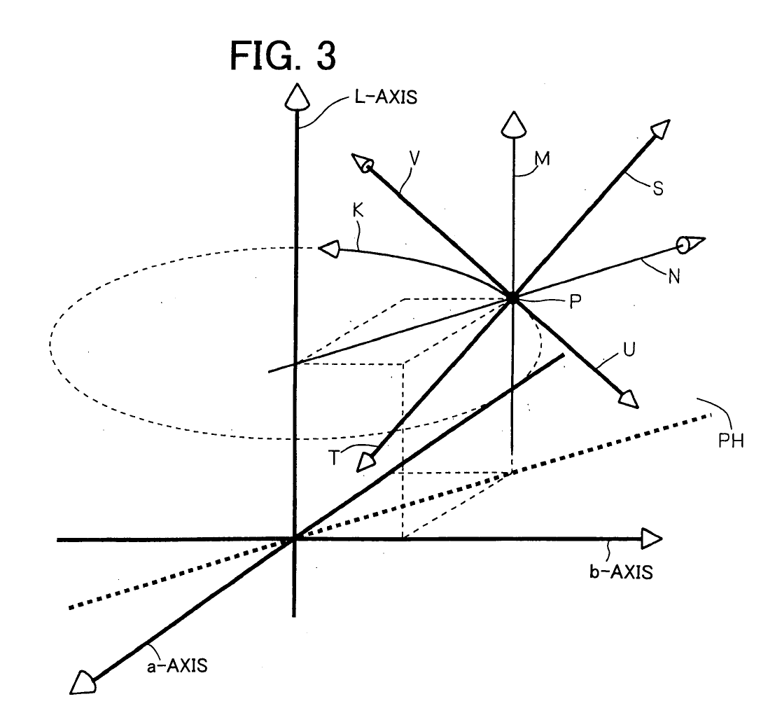

A property of the Lab color space relating to the following respective preferred embodiments will now be described. FIG. 3 is a drawing illustrating a Lab color space. The Lab color space is defined by an L-axis, an a-axis and a b-axis. The lightness is defined by an L-coordinate, the hue is defined by a ratio between an a-coordinate and a b-coordinate, and the saturation is defined by a distance from the L-axis. For example, assuming that the coordinates of a point P in a Lab space is (ap, bp, Lp), a lightness L (P), a saturation C (P) and a hue H (P) of the point P are expressed as follows.

[Formula 1]

$$\begin{matrix} L ( P ) = Lp & ( expression 1 ) \\ C ( P ) = \sqrt{{ap}^{2}} + {bp}^{2} & ( expression 2 ) \\ H ( P ) = {tan}^{- 1} [ \frac{bp}{ap} ] & ( expression 3 )\end{matrix}$$

In other words, moving the point P in the positive direction of an arrow M in FIG. 3 corresponds to an increase of the lightness while maintaining the hue and the saturation. Meanwhile, moving the point P in the negative direction of the arrow M corresponds to a decrease of the lightness while maintaining the hue and the saturation. For example, when an increase of the brightness of the point P by ΔL is desired, the point P is moved in the positive direction of the arrow M by ΔL.

Moving the point P in the positive direction of an arrow N corresponds to an increase of the saturation while maintaining the hue and the lightness. Meanwhile, moving the point P in the negative direction of the arrow N corresponds to a decrease of the saturation while maintaining the hue and the lightness. For example, when an increase of the saturation of the point P by ΔC is desired, the point P is moved in the positive direction of the arrow N by ΔC.

Moving the point P in the direction of an arrow K corresponds to changing the hue while maintaining the lightness and the saturation. For example, when a change of the hue of the point P by ΔH is desired, the point P is rotated by an angle ΔH about the L-axis in the direction of the arrow K.

In other words, with respect to the point P in the Lab color space, M is the axis of lightness, N is the axis of saturation, and K is the axis of hue.

The sensuous terms (terms expressed by a color sense of a human being) relating to the color tone used in a daily life also have certain directional properties in this Lab color space. In other words, in case the term “bright” is used as an expression when the point P is moved in a certain direction, this direction is a directional property possessed by the term “bright”. Likewise, the sensuous terms relating to the color tone such as “dark”, “deep” and “pale” also have certain directional property in the Lab color space, respectively.

The terms “bright” and “dark” are a pair of terms which have opposite meanings. Therefore, the directional property possessed by these terms are opposite from each other. The terms “deep” and “pale” are also a pair of terms which have opposite meanings.

FIG. 3 illustrates the directional properties possessed by the sensuous terms relating to four color tones “bright”, “dark”, “deep” and “pale” in the Lab color space by an arrow S, an arrow T, an arrow U and an arrow V in reference to the point P. The arrow S indicates the direction to increase the “brightness” of the point P. Likewise, the arrows T, U and V indicate the direction to increase the “darkness”, “deepness” and “paleness”. In other words, for example, when an increase of the “brightness” of the point P by ΔS is desired, the point P is moved in the direction of the arrow S by ΔS. The most suitable directional property is defined by idiomaticity of the respective terms (words).

In FIG. 3, the respective arrows S and T of the pair of two terms described above, that is, the terms “bright” and “dark” are aligned and indicate opposite directions from each other. It is the same for the respective arrows U and V for “deep” and “pale”.

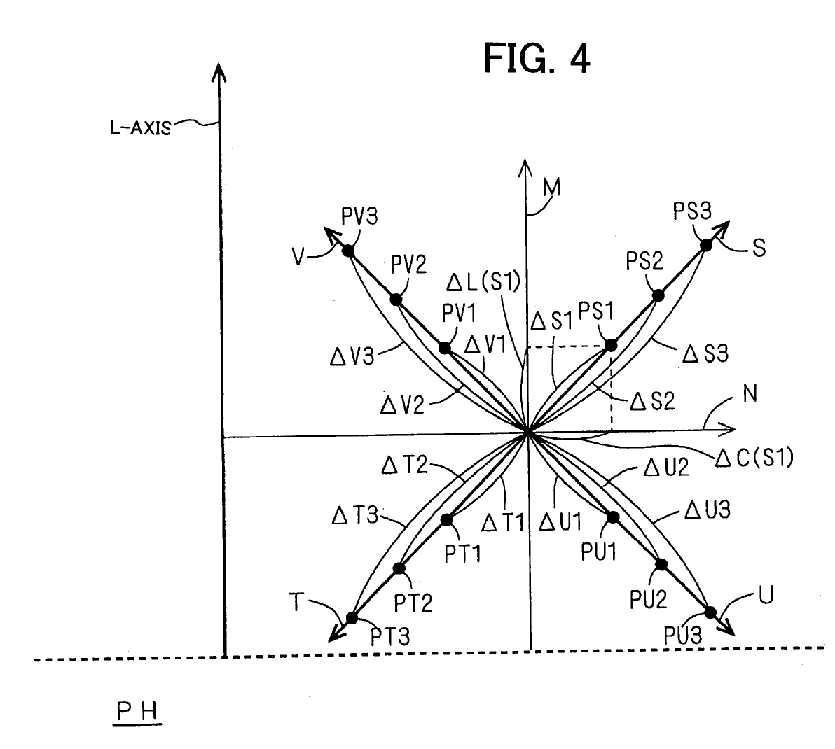

These four sensuous terms are not associated with a change of the hue. In other words, these arrows all indicate the directional properties which maintain the hue in the Lab color space. Therefore, assuming that a plan PH designates a plan of the identical hue including the point P in the Lab color space, the arrows S to V are all on the plan PH. FIG. 4 is a drawing illustrating the plan PH.

As will be seen in FIG. 4, the arrows S to V are straight lines positioned on a plan defined by the direction of lightness M and the direction of saturation N. What is important here is that the directions of the color adjustment expressed by these sensuous terms are not parallel to one of the direction of lightness M and the direction of saturation N, and is a direction inclined with respect both to the direction of lightness M and the direction of saturation N (the combined direction of change). In other words, an expression “to make it brighter” as the sensuous terms (daily words) does not match the expression “to increase lightness” in the uniform color space and includes a factor of “reducing the deepness” in the uniform color space. Likewise, the expression “to make it deeper” as the sensuous terms does not match the expression “to increase deepness” in the uniform color space, and includes a factor of “reducing the lightness” in the uniform color space. In general, the general user of the digital color complex machine rarely inputs the instruction of the color adjustment corresponding to the terms in the uniform color space, and in most cases, the user wishes to give an instruction of the color adjustment according to the sensuous terms. Therefore, it is effective to configure the color adjusting function of the digital color complex machine 100 in view of such circumstances. The directional properties S to V possessed by the respective sensuous terms in the Lab color space can be defined by the relative relation between the lightness and the saturation, that is, by the relative relation between the amount of change in lightness ΔL and the amount of change in saturation ΔC.

The color adjustment in the respective preferred embodiment shown below is the color adjustment which matches the respective sensuous terms performed by defining the directional properties S to V possessed by the respective sensuous terms in the Lab color space by the relative relation between the amount of change in lightness ΔL and the amount of change in saturation ΔC, and changing the lightness and the saturation of the image data according to the relative relation.

Subsequently, detailed modes of the color adjustment of the second image processing (step S4 in FIG. 2) by the input image processing unit 3 will be described for each preferred embodiment.

### 3. First Preferred Embodiment

FIG. 1 illustrates a structure of the input image processing unit 3. The input image processing unit 3 includes a Central Processing Unit (CPU) 11 for controlling the input image processing unit 3, a Read Only Memory (ROM) 12 for storing a control program and a conversion table and so on, and a Random Access Memory (RAM) 13 for storing image data or the like temporarily as illustrated in FIG. 1. The input image processing unit 3 also includes an operating unit 14 that is used by the user for entering various instructions, and a display unit 15 for displaying various screens. In the digital color complex machine 100 according to the preferred embodiment, the display unit 15 includes a flat panel display. The operating unit 14 may be configured by an array of buttons to which functions are fixedly allocated, and may be configured of a touch screen arranged on a display surface of the flat panel display. The operating unit 14 may also be a combination of these two systems. A description will be continued with reference to an example in which the operating unit 14 is achieved by the array of buttons to which the functions are fixedly allocated.

The operating unit 14 includes a duplicated selection prohibiting unit 141. Although the duplicated selection prohibiting unit 141 is illustrated as a component of the operating unit 14 for the sake of convenience, a function of the duplicated selection prohibiting unit 141 may be achieved by the CPU 11 and the RAM 13 based on the program stored in the ROM 12.

The input image processing unit 3 includes a first image processing unit 16, a color space converting unit 17 and a second image processing unit 18, and the first image processing, a conversion from the RGB image data to the Lab image data, and the second image processing described above are executed in each functional unit. The second image processing unit 18 is segmentalised into a scaling unit 181 and a color adjustment unit 182, and the scaling and color adjustment described above are performed in each functional unit. Although functions of the first image processing unit 16, the color space converting unit 17 and the second image processing unit 18 can also be achieve by the cooperation of the CPU 11 and the RAM 13 based on the program stored in the ROM 12, these members are illustrated outside these factors 11, 12, and 13 for convenience.

The color adjustment unit 182 in the first preferred embodiment has four color adjusting modes relating to the respective “to make it brighter”, “to make it darker”, “to make it deeper” and “to make is paler” (hereinafter, referred respectively to as “bright mode”, “dark mode”, “deep mode” and “pale mode”). For example, in the “bright mode”, the color of the entire Lab image data is adjusted to be “brighter” by moving the respective factors of the Lab image data of the original image in the direction of the arrow S in FIG. 4. In the same manner, in the “dark mode”, the “deep mode” and the “pale mode”, the color adjustments represented by the respective sensuous terms are performed by moving the respective factors of the Lab image data in the direction of the arrows T, U and V respectively. The terms “to make it brighter” and “to make it darker” represent changes of the “brightness” in the positive and negative directions. Hence, the terms “to make it brighter” and “to make it darker” can be referred generically to as a “brightness/darkness adjusting mode”. The terms “to make it deeper” and “to make it paler” represent changes of “deepness” in the positive and negative directions. Hence, the terms “to make it deeper” and “to make it paler” can be referred generically to as a “deepness/paleness adjusting mode”. A detailed mode of the color adjustment by these color adjusting modes will be described below.

3-1. Selection of Color Adjusting Modes

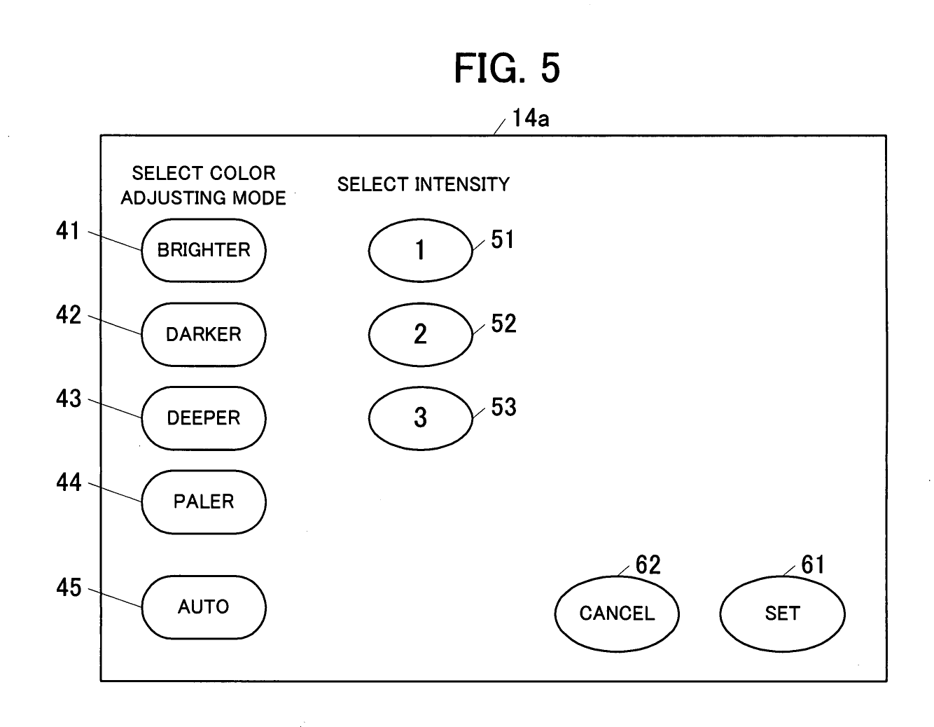

Firstly, a selection of the color adjusting modes will be described. FIG. 5 is a drawing of an appearance of the operating unit 14a in the first preferred embodiment illustrating a display when the color adjusting mode is selected. The operating unit 14a includes buttons 41 to 45 which selectively specify five color adjusting modes. The respective buttons are marked with characters of “brighter”, “darker”, “deeper”, “paler” and “auto”, which signify “bright mode”, “dark mode”, “deep mode”, “pale mode”, and “automatic adjusting mode”, respectively. Buttons 51 to 53 for selecting the intensity of the respective color adjusting modes, a SET button 61 and a cancel button 62 are also arranged. Hereinafter, the buttons 41 to 45 are generally referred to as “color adjusting mode selection button”. The button 45 for selecting the automatic adjusting mode is specifically referred to as “auto mode button”, and the four buttons 41 to 44 for performing a color adjustment according to the instructions given by a manual operation are distinctively referred to as “manual color adjusting mode selection button”.

When the user wishes to carry out the color adjustment automatically, the color adjustment is performed automatically by operating the auto mode button 45, and then, operating the SET button 61. When “no color adjustment” is allocated instead of the auto mode button 45, a mode in which no color adjustment is performed is selected.

When the user wishes to make the image to be copied from the manuscript “brighter”, the user selects and operates the button 41 (“bright mode” selection button) marked with “brighter” out of the color adjusting mode selection buttons 41 to 45. Then, the user selects the extent of brightness from the intensity selection buttons 51 to 53 and operates the same. In this case, a selection from three intensities is possible, and the larger the number marked on the buttons 51 to 53, the more intensive the color adjustment becomes. When one of the color adjusting mode selection buttons 41 to 44 and one of the intensity selection buttons 51 to 53 are operated in sequence, an operation of the SET button 61 is enabled. When the SET button 61 is operated, the selected color adjusting mode and the intensity are transmitted from the operating unit 14a to the second image processing unit 18, and the color adjustment is executed.

A description will be made of a case in which a plurality of buttons out of the color adjusting mode selection buttons 41 to 44 are operated in a duplicated manner, for example, a case in which after the button 41 marked with “brighter” (“bright mode” selection button) and one of the intensity selection buttons 51 to 53 are operated, the button 44 marked with “paler” (“pale mode” selection button“) is operated. When the “paler” button 44 is operated before the SET button 61 is operated, the initial operation of the “brighter” button 41 is invalidated by the duplicated selection prohibiting unit 141.

More specifically, (1) selected mode information which is selected previously and stored in a predetermined memory area (hereinafter referred to as “mode registration area”) (information that the “bright” mode is selected in this case) and the selected intensity information (information on intensity selected from (1) to (3)) are cancelled, and the default state (for example, the auto mode or the no color adjusting mode) is restored, then, (2) information that the “pale” mode is selected newly is stored as the selected mode information, and the intensity selected by one of the intensity selection buttons 51 to 53 as the intensity information in “bright” mode are stored in the mode registration area, respectively.

Although an update operation is achieved by performing a cancellation of the registration and a new registration separately, when an update of the information is performed by overwriting new information directly on the previous information, the above-described steps (1) and (2) are executed substantially in one step.

On the other hand, when the “bright mode” is selected and the SET button 61 is operated, and then, the “paler” button 44 is operated, the validity of the “paler” button 44 is invalidated by the duplicated selection prohibiting unit 141. In other words, the latest selection is given priority before operating the SET button 61, and once the SET button 61 is operated, the previous selection is given priority.

In this manner, a duplicated selection of two or more color adjusting modes is prohibited by the duplicated selection prohibiting unit 141. Although the description above is applied to duplication among the color adjusting mode selection buttons 41 to 44, the duplicated selection is prohibited also between the manual color adjusting mode selection buttons 41 to 44 and the auto mode button 45.

When only the mode selection is changed without operating the intensity selection buttons 51 to 53, for example, when the “pale mode” selection button 44 is operated immediately after the operation of the “bright mode” selection button 41 as well, information of the “bright mode” is cleared, and the “pale mode” is newly set. This is also the duplicated selection prohibiting function. In this case, in comparison with the case in which the user operates any one of the intensity selection buttons 51 to 53 for the “bright mode”, and then the “pale mode” is newly selected, there is a difference in an intension of the user in many cases.

In other words, in the case in which the first mode selection and the first intensity selection are performed, and then the next mode selection and the next intensity selection are performed, it is considered that the user has an intension to perform the duplicated selection of the color adjustment in the mode selected first (first color adjustment) and the color adjustment in the mode selected next (second color adjustment) in many cases. The reason why such a duplicated selection is prohibited in the digital color complex machine 100 in this preferred embodiment is that the four preset color adjusting modes are not independent from each other, and hence the color adjustment in one mode affects the color adjustment in other modes. Therefore, if the duplicated selection of the modes is permitted, the color adjustment in which the intention of the user is not reflected may result in quite many cases.

For example, the color adjustment to “brighten” and “deepen” the image may reflect a specific intention of the user subjectively. However, this intension can hardly be understood objectively. For example, it may be understood to be an intention to increase a contrast, or to increase the lightness and the saturation. Therefore, if such a duplicated selection is permitted, the color adjustment which does not reflect the intention of the user is performed instead, and the user is confused in many cases. In other words, a significance of prohibition of the duplicated selection in this case is based on avoidance of “interference among color adjusting modes” due to mutual dependence (inorthogonality) of the directions of the respective color adjustment in the color space.

Meanwhile, in a case in which a mode is specified by the user with one manual color adjusting mode selection button, and then another manual color adjusting mode selection button is operated before selecting the intensity, it is estimated to be a correction of an erroneous selection of the mode in many cases. It is also the same in the case of a consequent operation of the intensity selection buttons. The prohibition of the duplicated selection in this case reflects the intention of the user who did not make the duplicated selection intentionally.

The state of operation of the button and these two causes do not necessarily correspond to each other completely in one-to-one relation. There may be a case in which the former is the correction of the erroneous selection and the latter is a result of a positive intension of the duplicated selection. Hence, these two causes exist in a mixed manner in a practical sense. The duplicated selection prohibiting function of the digital color complex machine 100 in this preferred embodiment has a complex significance such that both of these causes are supported.

When only the intensity selection buttons 51 to 53 are operated in a duplicated manner, for example, when the “paler” button 44 is operated, and then the intensity selection button 51 and another intensity selection button 52 are consecutively operated, a possibility of a corrective selection of the intensity based on a voluntary intension of the user is high. Hence, a mode in which the intensity information is rewritten from the previous “1” to the new intensity “2” and the setting of “pale mode” made via the manual color adjusting mode selection button 41 is not reset may be achieved.

In other words, it is preferable to prohibit the duplicated selection of the color adjusting mode, while in the case of the consecutive operation of the intensity by itself, the user can understand that the concept of “duplicated selection of the intensity” cannot happen, and hence it is preferable to treat such a consecutive operation as the corrective operation to reflect the intension of the user. Therefore, in this preferred embodiment, when the selection of the intensity is consecutively performed, the registration of the intensity is updated, and the registration information of the color adjusting mode is unchanged. However, when the operation to select the color adjusting mode is newly done subsequently, both of the color adjusting mode and the intensity are reset, and the color adjusting mode is rewritten to reflect the latest selection.

Which color adjusting mode and the intensity are selected at the moment can be notified easily to the user by controlling the display such as to display the selected buttons in darker colors than other buttons using a variable display property of the display unit 15. Accordingly, an erroneous operation by the user can be prevented.

On the other hand, when the user operates the cancel button 62 before operating the SET button 61, the selected mode information and the selected intensity information which are already entered and registered are compulsively reset (cleared). As described above, with the digital color complex machine 100 in this preferred embodiment, when the color adjusting mode selection buttons 41 to 45 or the intensity selection buttons 51 to 53 are newly operated, the mode or the intensity which are previously selected are reset. Hence, the erroneous input can be corrected without the operation of the cancel (reset) button 62 by the user. However, since there is a case in which the user does not know about such a duplicated selection prohibiting function, user-friendliness is increased by providing the cancel button 62. When the auto mode button 45 is not provided, any one of the manual color adjusting modes is selected once, and then the cancel button 62 may be operated for a purpose of correcting the color adjustment to a default setting (auto mode or no color adjustment).

The duplicated selection prohibiting unit 141 can be configured in a mode different from the one shown above. That is, it is also applicable to display a message such as “Duplicated setting of color adjustment in different modes is not allowed. Press cancel button once to cancel the previous selection” on the display unit 15 and give a predetermined warning tone from a sound source (not illustrated) provided in the digital color complex machine 100 when a duplicated operation is performed, instead of compulsively resetting the previously selected mode information or the selected intensity information upon the duplicated operation of the color adjusting mode selection buttons 41 to 45 or the intensity selection buttons 51 to 53.

3-2. Adjustment Coefficient

Next, an adjustment coefficient will be described. The adjustment coefficient is stored in the ROM 12 as a table TB for each color adjusting mode and each intensity.

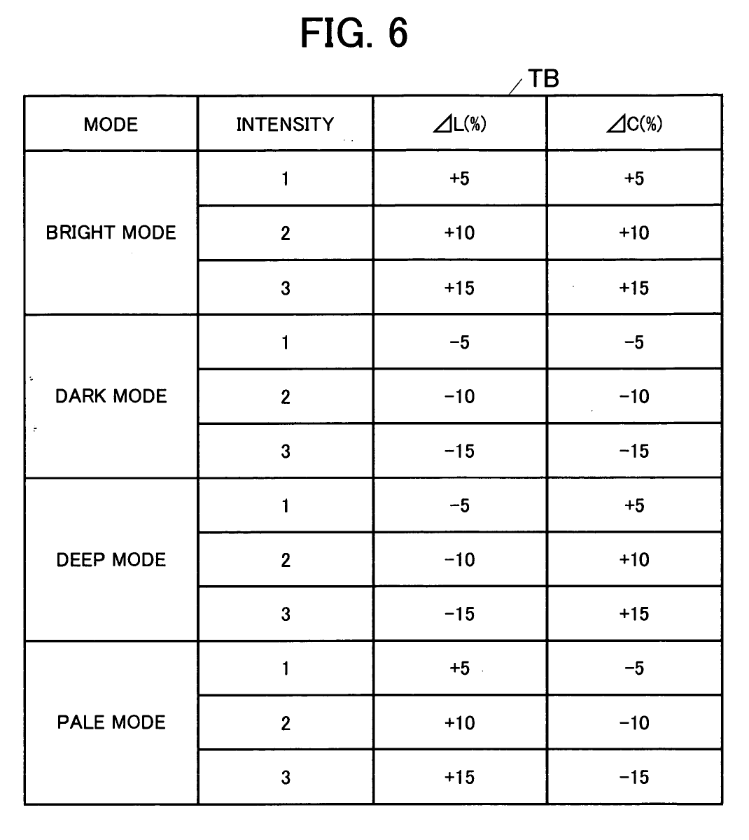

FIG. 6 illustrates an example of an adjustment coefficient table TB. As described previously, the “bright mode” corresponds to the movement of the respective factors of the Lab image data of the original image by AS in the direction of the arrow S illustrated in FIG. 4. Likewise, the “dark mode”, the “deep mode” and the “pale mode” correspond to the movement by ΔT, ΔU and ΔV in the directions of the arrows T, U and V.

Here, the value of AS is a factor to define the intensity of the adjustment. The larger AS is, the larger the extent of becoming “brighter”. In other words, the “bright mode” of the intensities 1, 2 and 3 are PS1, PS2 and PS3 obtained by moving the point P by ΔS1, ΔS2 and ΔS3 respectively in the S-direction (see FIG. 4). It is the same in the “dark mode”, and the “dark mode” of the intensities 1, 2 and 3 are PT1, PT2 and PT3 obtained by moving the point P by ΔT1, ΔT2 and ΔT3 respectively in the T-direction. It is also the same in the “deep mode” and the “pale mode”.

As described previously, in order to move the point P in the directions of the arrows S, T, U and V, the lightness and the saturation of the point P may simply be changed, and the amount of change in lightness ΔL and the amount of change in saturation ΔC have a certain relative relation. The values of the amount of change in lightness ΔL and the amount of change in saturation ΔC according to the relative relation listed for each color adjusting mode and the intensity is the adjustment coefficient table TB. For example, according to the adjustment coefficient table TB in FIG. 6, the amount of change in lightness ΔL (S1) required for moving the point P by ΔS1 in the “bright mode” with the intensity 1 is +5% of the brightness Lp of the point P.

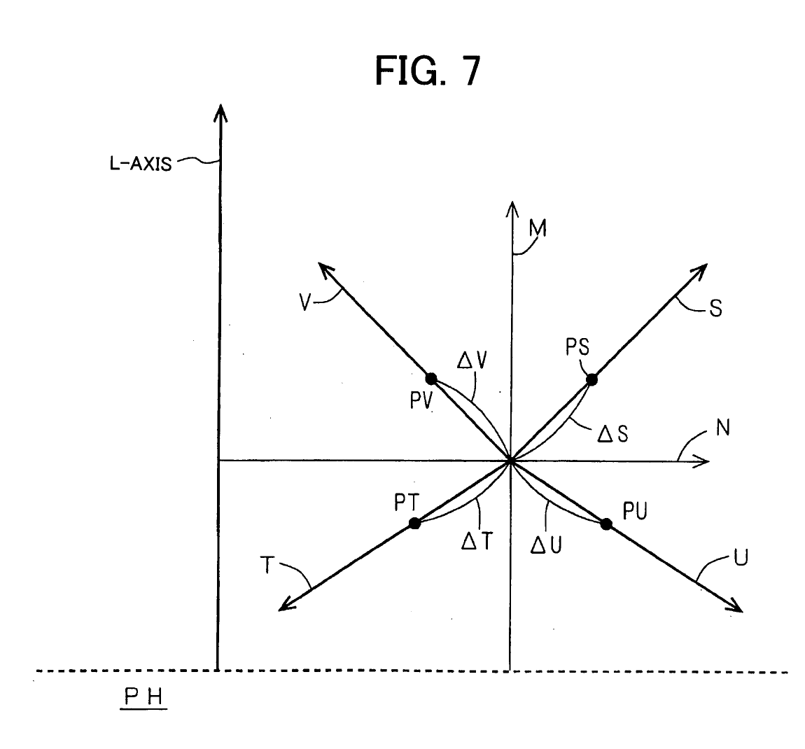

In addition, according to the adjustment coefficient table TB in FIG. 7, in the respective “bright mode”, “dark mode”, “deep mode” and “pale mode”, the amount of change in lightness ΔL and the amount of change in saturation ΔC have a following relative relation.

[Formula 2]
ΔL(S)=ΔC(S) (expression 4)
ΔL(T)=ΔC(T) (expression 5)
ΔL(U)=−ΔC(U) (expression 6)
ΔL(V)=−ΔC(V) (expression 7)

In other words, in the “bright mode” and the “dark mode” which belong to the “brightness” adjusting mode, the lightness component and the saturation component are relatively increased or decreased by the same positive or negative sign. In the “deep mode” and the “pale mode” which belong to the “deepness” adjusting mode, the lightness component and the saturation component are relatively increased or decreased by the opposite positive and negative signs.

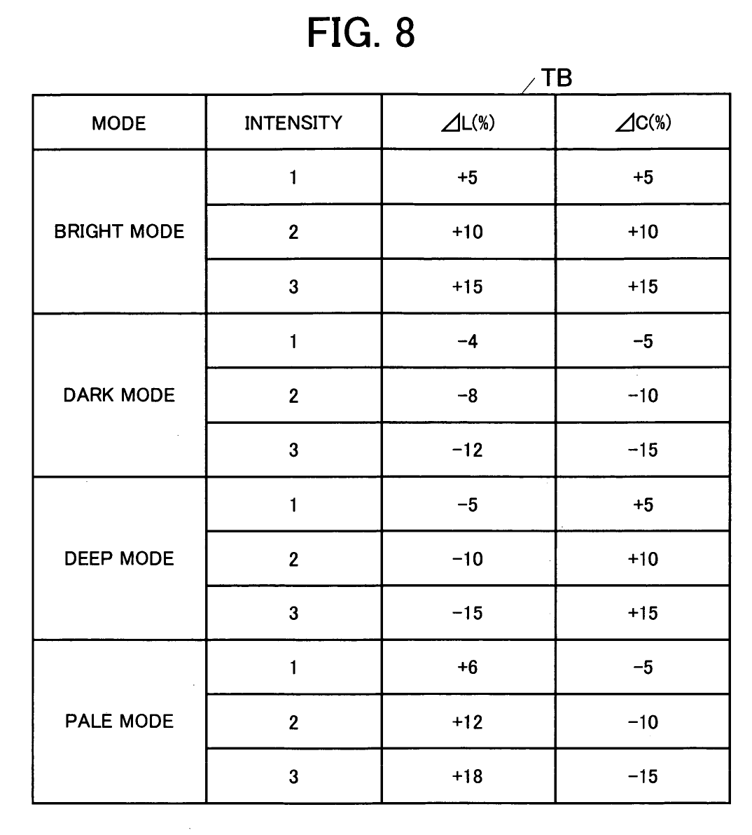

FIG. 8 is a drawing illustrating an example of the adjustment coefficient table TB based on another relative relation. The adjustment coefficient table TB in FIG. 8 shows values obtained by moving the respective factors of the Lab image data of the original image by ΔS, ΔT, ΔU and ΔV respectively in the directions of the arrows S, T, U and V in FIG. 7. According to the adjustment coefficient table TB in FIG. 8, in the respective “bright mode”, “dark mode”, “deep mode” and “pale mode”, the amount of change in lightness ΔL and the amount of change in saturation ΔC have the following relative relation.

[Formula 3]
ΔL(S)=ΔC(S)
ΔL(T)=0.8ΔC(T)
ΔL(U)=−ΔC(U)
ΔL(V)=−1.2ΔC(V)

Since the arrows S and T are not on the identical straight line in FIG. 7, the ratio of change of the amount of change in lightness ΔL with respect to the amount of change in saturation ΔC are different between the “bright mode” and the “dark mode”. It is the same between the “deep mode” and the “pale mode”.

3-3. Color Adjustment

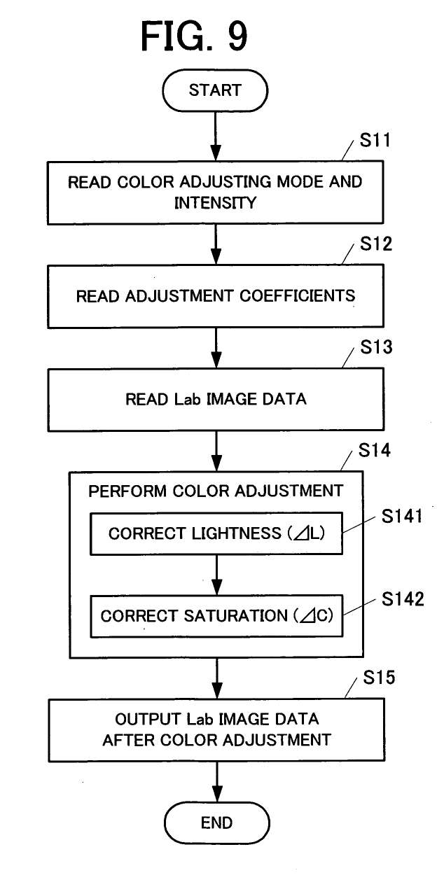

Subsequently, the color adjustment operation in the color adjustment unit 182 will be described. FIG. 9 is a flowchart illustrating a color adjustment operation in the color adjustment unit 182.

Firstly, information on the color adjusting mode and the intensity selected by operating the operating unit 14 is taken in (step S11). Next, the values of the adjustment coefficients ΔL and ΔC in the selected color adjusting mode and the intensity are read from the adjustment coefficient table TB stored in the ROM 12 (step S12).

Then, the Lab image data of the original image is read (step S13), and the color adjustment is executed according to the adjustment coefficient read in step S12 (step S14). The Lab image data on which the color adjustment is executed is outputted to the output image processing unit 3 (step S15).

The color adjustment in step S14 will be described further in detail below. First, the brightness of the Lab image data which is read in step S13 is corrected by ΔL which is read in step S12 (step S141).

In the Lab image data, the respective pixels of the original image is expressed by the coordinates in the Lab color space, and the lightness L(P) of the point P having the coordinates (ap, bp, Lp) is expressed by the expression 1. Therefore, assuming that the coordinates of a point Q obtained by correcting the lightness of the point P by ΔL are (aq, bq, Lq), expressions 8 to 10 shown below are established.

[Formula 4]
aq=ap (expression 8)
bq=bp (expression 9)
Lq=Lp+ΔL (expression 10)

The coordinates of the point Q can be obtained by the expressions 8 to 10, and the lightness of the Lab image data can be corrected by ΔL by obtaining the coordinates after correction for the respective factors of the Lab image data.

In the adjustment coefficient table TB in FIG. 6, since ΔL is defined by %, ΔL depends on Lp. For example, in the case of “bright mode” with the intensity 1, an expression 11 shown below is established, and in the case of the “deep mode” with the intensity 2, an expression 12 shown below is established.

[Formula 5]
Lq=Lp+0.05Lp (expression 11)

[Formula 6]
Lq=Lp+(−0.10)Lp (expression 12)

Subsequently, the saturation of the Lab image data read in step S13 is corrected by ΔC read in step S12 (step S142).

In the Lab image data, the respective pixels of the original image are expressed by the coordinates in the Lab color space, and the saturation C (P) of the point P with the coordinates (ap, bp, Lp) is expressed by the expression 2. Therefore, assuming that the coordinates of a point R obtained by correcting the saturation of the point P by ΔC are (ar, br, Lr), relational expressions 13 to 15 shown below are established. “ar” has the same sign as “ap”, and “br” has the same sign as “bp”. The coordinates of the point R can be obtained from the relational expressions 13 to 15, and the saturation of the Lab image data can be corrected by ΔC by obtaining the coordinates after correction for the respective factors of the Lab image data.

[Formula 7]

$$\begin{matrix}\sqrt{{ap}^{2} + {bp}^{2}} + Δ C = \sqrt{{ar}^{2} + {br}^{2}} & ( expression 13 ) \\ \frac{bp}{ap} = \frac{br}{ar} & ( expression 14 ) \\ Lr = Lp & ( expression 15 )\end{matrix}$$

In the adjustment coefficient table TB in FIG. 6, since ΔC is defined by %, ΔC depends on ap and bp. For example, in the case of the “bright mode” with the intensity 1, an expression 16 shown below is established, and hence expressions 17 and 18 are established. In the case of “pale mode” with the intensity 2, an expression 19 shown below is established, and hence expressions 20 and 21 are established. The color adjustment in step S14 is executed as described thus far. Consequently, the color adjusted Lab image data on which the color adjustment according to the respective color adjusting modes is performed is obtained.

[Formula 8]
\sqrt{ap²+bp²}+0.05\sqrt{ap²+bp²}=\sqrt{ar²+br²} (expression 16)

[Formula 9]
ar=1.05ap (expression 17)
br=1.05bp (expression 18)

[Formula 10]
\sqrt{ap²⁺bp²}+(−0.10)\sqrt{ap²+bp²}=ar²+br² (expression 19)

[Formula 11]
ar=0.9ap (expression 20)
br=0.9bp (expression 21)

Although the lightness and the saturation are linearly changed according to the predetermined adjustment coefficient in the description above, it is also possible to perform a correction in which they are changed nonlinearly. For example, a nonlinear function as an expression 22 shown below can be used.

[Formula 12]
y=x^{r} (expression 22)

That is, γ is a predetermined value stored in the adjustment coefficient table TB for each color adjusting mode and each intensity. Values x and y are values obtained by normalizing the lightness Lp of the Lab image data read in step S13 and the lightness Lq after correction into the range from 0 to 1. For example, an expression to obtain the value x from the value of Lp is an expression 23 shown below. A defined area of the lightness is assumed to be 0 to Ld.

[Formula 13]

$$x = \frac{Lp}{Ld} \qquad ( expression 23 )$$

In the same manner, the lightness Lq after the correction can be obtained from the value y. The same correction to cause a nonlinear change can be performed for the saturation.

By setting the value γ to a value larger than 1, an output value which is smaller than the input value can be obtained. By setting the value γ to a value smaller than 1, an output value which is larger than the input value can be obtained. For example, when the output value smaller than the input value is desired, if the value of the maximum value Ld in the defined area of the brightness is 255, the value γ may simply be set to 1.8.

The process to correct and output the supplied values such as the lightness or the saturation can be achieved by storing a program for converting the input value to the predetermined output value in the ROM 12 in advance as described above. It is also possible to be realized by storing the output value in the memory in advance, and using the RAM 13 which converts the input value to the output value by referring the input value as an address. Furthermore, it is possible to be realized by a hardware obtaining the calculated result (output value) instead of using the RAM 13.

### 4. Second Preferred Embodiment

In the first preferred embodiment, the “brightness/darkness adjusting mode” is configured as the pair of “brighter” and “darker” modes while the “deepness/paleness adjusting mode” is configured as the pair of “deeper” and “paler” modes. Meanwhile, in the color adjustment unit 182 in a second preferred embodiment, substantially the same function as the first preferred embodiment is achieved by combining these pairs into a single color adjusting mode respectively, and selecting the positive or negative sign as the direction of change.

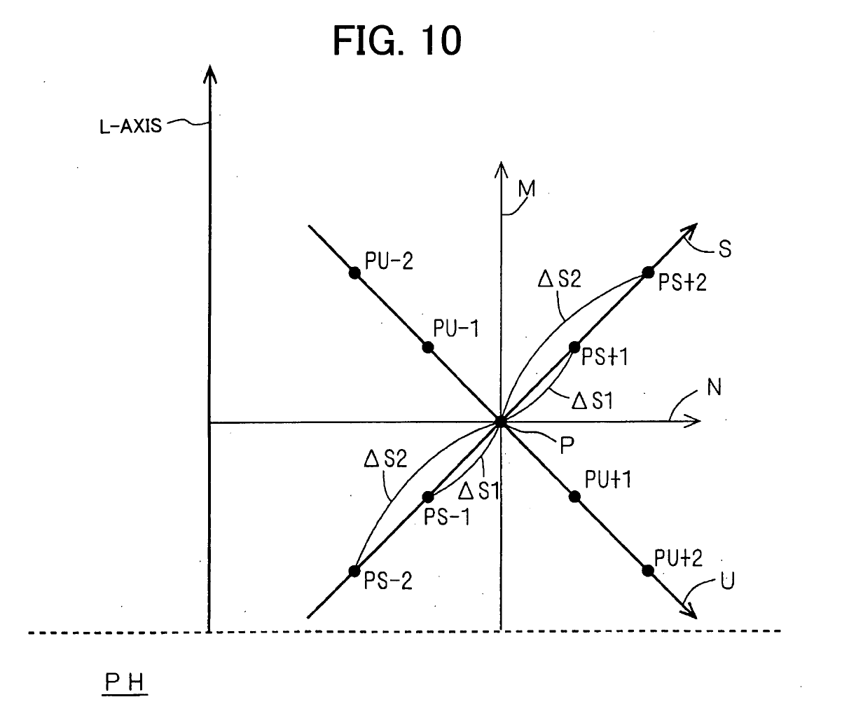

FIG. 10 is a drawing illustrating the plan PH in the Lab color space. In the second preferred embodiment, FIG. 10 has the same signification as FIG. 4 in the first preferred embodiment. Moving the point P in the directions of the arrows S, T, U and V in FIG. 4 corresponds to an increase of the “brightness”, the “darkness”, the “deepness” and the “paleness”. In the second preferred embodiment, the “brightness” is increased by moving the point P in the positive direction of the arrow S, and the “brightness” is reduced by moving the point P in the negative direction of the arrow S. This corresponds to an increase in the “darkness”. That is, in the second preferred embodiment, the color adjustment regarding the “brightness”, the “darkness”, the “deepness” and the “paleness” are enabled respectively by the adjustment in the positive direction and the negative direction in the two directional properties of “brightness/darkness adjusting mode” and “deepness/paleness adjusting mode”, not in the four directional properties. In other words, the color adjustment to a “darker” image is achieved by reducing the “brightness”, and the color adjustment to a “paler” image is achieved by reducing the “deepness”.

4-1. Selection of Color Adjusting Mode

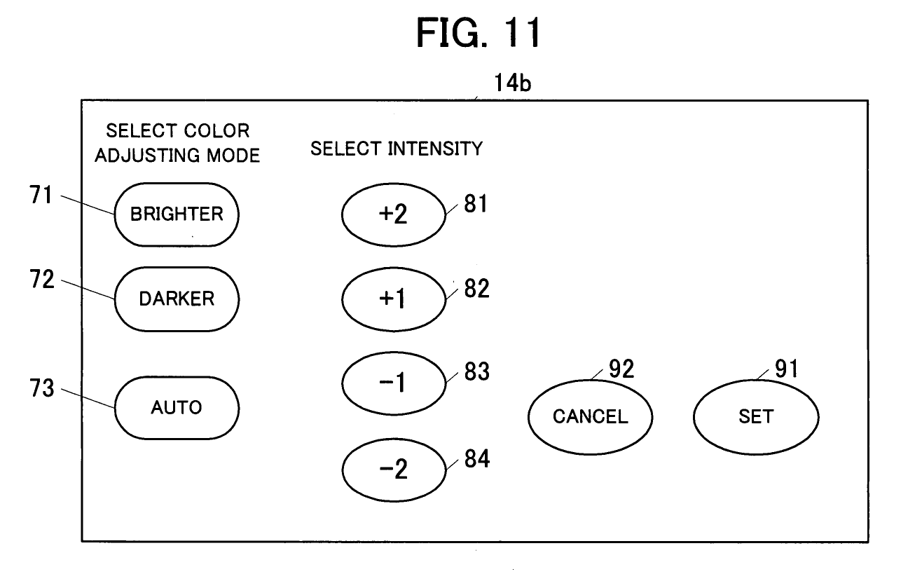

FIG. 11 is an appearance drawing illustrating a related portion of the operating unit 14b in the second preferred embodiment. The operating unit 14b includes buttons 71 to 73 for selecting three color adjusting modes. The respective buttons are marked with “brighter”, “darker” and “auto”, which signify “bright mode”, “deep mode” and “auto mode”. Buttons 81 to 84 for selecting the intensity in the respective color adjusting modes and a SET button 91 and a cancel button 92 are also arranged.

When the user wishes to make the image which is obtained by copying the manuscript “brighter”, the user selects and operates the button 71 (brightness/darkness adjusting mode selection button) marked with “brighter” out of the color adjusting mode selection buttons 71 to 73. Then, the user selects and operates the extent to make the image brighter from the two buttons 81 and 82 having a positive sign out of the intensity selection buttons 81 to 84.

On the other hand, when the user wishes to make the image which is obtained by copying the manuscript “darker”, the user selects and operates the button 71 (brightness/darkness adjusting mode selection button) marked with “brighter” out of the color adjusting mode selection buttons 71 to 73. Then, the user selects and operates the extent to make the image brighter from the two buttons 83 and 84 having a negative sign out of the intensity selection buttons 81 to 84.

The selection of the color adjusting mode relating to “deepness and paleness” is also the same. The duplicated selection prohibiting function among the color adjusting mode selection buttons 71 to 73 is also provided in the same manner as in the first preferred embodiment.

4-2. Adjustment Coefficients

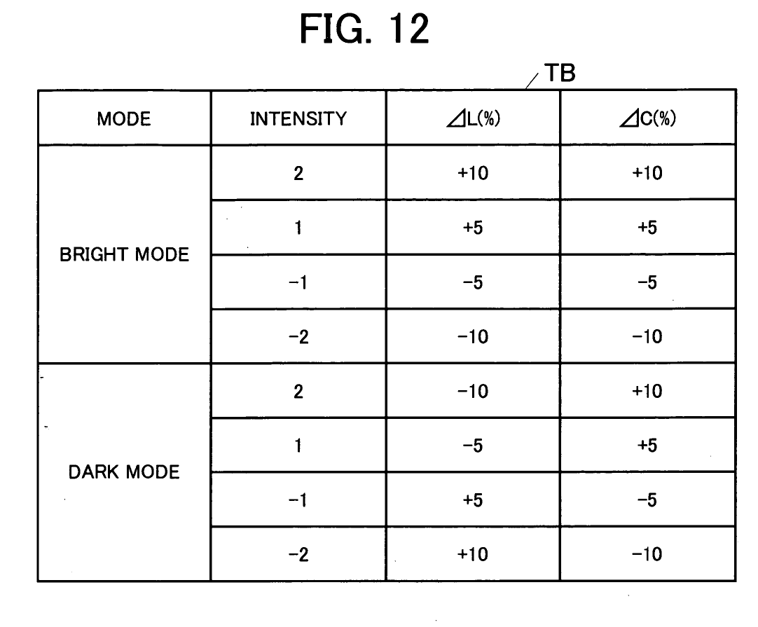

FIG. 12 is a drawing illustrating an example of the adjustment coefficient table TB in the second preferred embodiment. As described previously, the “bright mode” has a function to move the respective factors of the Lab image data of the original image by ΔS in the positive or the negative direction of the arrow S illustrated in FIG. 10. In the same manner, the “deep mode” has a function to move the respective factors of the Lab image data of the original image by ΔU in the positive or the negative direction of the arrow U.

The value of ΔS is a factor for defining the intensity of adjustment. The larger the value of ΔS is in the positive direction, the larger the extent to be “brighter” becomes. The larger the value of AS is in the negative direction, the larger the extent to be “darker” becomes. In other words, the “bright mode” with the intensity of +2, +1, −1 and −2 respectively corresponds to PS+2, PS+1, PS−1 and PS−2 obtained by moving the point P by ΔS2, ΔS1 in the positive and the negative directions of the arrow S (see FIG. 10). It is the same in the case of the “dark mode”.

As described previously, for example, in order to move the point P by ΔS in the positive direction of the arrow S, the lightness and the saturation of the point P may simply be changed according to the adjustment coefficient table TB. According to the adjustment coefficient table TB in FIG. 12, it will be seen that there is a relative relation as shown by the following expressions 24 and 15 between the amount of change in lightness ΔL and the amount of change in saturation ΔC in the “bright mode” and the “dark mode”, respectively.

[Formula 14]
ΔL(S)=ΔC(S) (expression 24)
ΔL(U)=−ΔC(U) (expression 25)

4-3. Color Adjustment

The color adjustment operation by the color adjustment unit 182 in the second preferred embodiment is the same as in the first preferred embodiment.

### 5. Other Preferred Embodiments

The first preferred embodiment includes four color adjusting modes that can select manually three levels of intensity, excluding the auto mode. The second preferred embodiment includes two color adjusting modes that can select manually four levels of intensity. It is also possible to provide more levels of intensity selection and more types of color adjusting modes.

In order to provide more levels of the intensity selection, a width of change in the directional property possessed by the respective color adjusting mode may be widened, or levels may be set more finely. In this case, the adjustment coefficient table TB corresponding to the respective intensity may be stored in the ROM 12. Alternatively, the relative relation between the amount of change in lightness ΔL and the amount of change in saturation ΔC may be stored as a program in the ROM 12, and the amount of change in lightness ΔL and the amount of change in saturation ΔC according to the selection of the intensity may be calculated by the interpolating calculation.

In order to provide the color adjusting modes corresponding to sensuous terms that express the color tone other than the sensuous terms described above, for example, the directional properties possessed by the sensuous terms in question in the Lab color space may be defined by the relative relation between the amount of change in brightness ΔL and the amount of change in saturation ΔC. The adjustment coefficient table TB can be created from this relative relation.

Since the sensuous terms described above each have an independent directional property from the hue, the adjustment coefficient table TB includes the amount of change in lightness ΔL and the amount of change in saturation ΔC. However, in case of sensuous terms which are not independent from the hue, the directional properties possessed by the sensuous terms in the Lab color space are defined by the relative relation among the amount of change in lightness ΔL, the amount of change in saturation ΔC and the amount of change in hue ΔH. That is, the adjustment coefficient table TB includes the amount of change in lightness ΔL, the amount of change in saturation ΔC and the amount of change in hue ΔH.

A mode in which a relative change of the two components of the amount of change in saturation ΔC and the amount of change in hue ΔH may be employed. For example, in case of a sensuous term of “warmer”, redness is relatively increased as the hue and simultaneously, the saturation of red is increased. In case of a sensuous term of “flesher”, blueness is relatively increased as the hue and simultaneously, the saturation of blue is increased.

While the present invention has been described with respect to preferred embodiments thereof, it will be apparent to those skilled in the art that the disclosed invention may be modified in numerous ways and may assume many embodiments other than those specifically set out and described above. Accordingly, it is intended by the appended claims to cover all modifications of the present invention that fall within the true spirit and scope of the invention.

What is claimed is:

1. A color image processing apparatus for executing a color adjustment on color image data, comprising:
an operation input means for giving an instruction on an increase or a decrease of a property expressed by a predetermined sensuous term relating to a color tone of the color image data; and
a color adjusting means for changing the color image data in a direction of change corresponding to the predetermined sensuous term in a predetermined color space in response to the instruction on the increase or the decrease, thereby executing the color adjustment of the color image data,
wherein the direction of change is a direction which relatively changes at least two components of a lightness component, a saturation component and a hue component of the color image data in the color space.

2. The color image processing apparatus according to claim 1, comprising a plurality of modes, in which a plurality of terms are defined different from each other as the sensuous term, for causing the respective color image data to be changed in a plurality of directions different from each other in the color space as the directions of change corresponding to the plurality of terms,
wherein the color adjusting means performs the color adjustment in a mode selected by the operation input means from the plurality of modes.

3. The color image processing apparatus according to claim 2, further comprising a prohibiting means for prohibiting duplicated inputs of instructions about the change of the respective color image data in the plurality of directions from the operation input means.

4. The color image processing apparatus according to claim 3, wherein the prohibiting means includes a compulsively canceling means which, in a case in which an instruction on the change of the color image data in one direction out of the plurality of directions is given from the operation input means and then an instruction on the change of the color image data in another direction out of the plurality of directions from the operation input means, compulsively cancels the instruction of the color adjustment which has already been given for the color image data in the one direction.

5. The color image processing apparatus according to claim 2, wherein the directions of change include two different directions for relatively changing a lightness component and a saturation component in the color space.

6. The color image processing apparatus according to claim 1, wherein the color adjusting means includes a “brightness” adjusting mode coordinated with the change in “brightness” as the sensuous term for causing the lightness component and the saturation component of the color image data to be relatively changed with the same positive or negative sign in response to the input of the instruction from the operation input means.

7. The color image processing apparatus according to claim 1, wherein the color adjusting means includes a “deepness” adjusting mode coordinated with the change in “deepness” as the sensuous term for causing the lightness component and the saturation component of the color image data to be relatively changed with opposite positive and negative signs in response to the input of the instruction from the operation input means.

8. The color image processing apparatus according to claim 2, wherein the plurality of terms include a plurality of terms which signify opposite meanings in pairs.

9. The color image processing apparatus according to claim 2, wherein the color adjusting means includes:
a first color adjusting mode for increasing the lightness component and increasing the saturation component;
a second color adjusting mode for decreasing the lightness component and decreasing the saturation component;
a third color adjusting mode for decreasing the lightness component and increasing the saturation component; and
a fourth color adjusting mode increasing the lightness component and decreasing the saturation component,
wherein a relative change between the lightness component and the saturation component in the first color adjusting mode has a directional property that matches a sense given by a term “brighter” as the sensuous term,
a relative change between the lightness component and the saturation component in the second color adjusting mode has a directional property that matches a sense given by a term “darker” as the sensuous term,
a relative change between the lightness component and the saturation component in the third color adjusting mode has a directional property that matches a sense given by a term “deeper” as the sensuous term, and
a relative change between the lightness component and the saturation component in the fourth color adjusting mode has a directional property that matches a sense given by a term “paler” as the sensuous term.

10. The color image processing apparatus according to claim 2, wherein the color adjusting means includes:
a first color adjusting mode for relatively increasing and decreasing the lightness component and the saturation component in the same direction; and
a second color adjusting mode for relatively increasing and decreasing the lightness component and the saturation component in the opposite directions,
wherein the relative change between the lightness component and the saturation component in the first color adjusting mode has a directional property that matches a sense given by the term “brighter” as the sensuous term, and
the relative change between the lightness component and the saturation component in the second color adjusting mode has a directional property that matches a sense given by the term “deeper” as the sensuous term.

11. A color image processing method for executing a color adjustment on color image data, comprising:
an operation input step that gives an instruction on an increase or a decrease of a property expressed by a predetermined sensuous term relating to a color tone of the color image data; and
a color adjusting step that changes the color image data in a direction corresponding to the predetermined sensuous term in a predetermined color space in response to the instruction on the increase or the decrease, thereby executing the color adjustment of the color image data,
wherein the direction of change is a direction which relatively changes at least two components of a lightness component, a saturation component and a hue component of the color image data in the color space.

12. The color image processing method according to claim 11, wherein the operation input step includes selecting any one of a plurality of modes for changing the color image data in a plurality of different directions in the color space as the direction of change, and
the color adjusting step includes executing the color adjustment in the mode selected from the plurality of modes in the operation input step.

13. The color image processing method according to claim 12, wherein the operation input step includes prohibiting duplicated inputs of the instructions on the changes of the color image data in the plurality of directions.

14. The color image processing method according to claim 13, wherein the operation input step includes, in a case in which an instruction on the change of the color image data in one direction out of the plurality of directions is given and then an instruction on the change of the color image data in another direction out of the plurality of directions is given, compulsively canceling the instruction of the color adjustment which has already been given for the color image data in the one direction.

15. The color image processing method according to claim 12, wherein the directions of change include two different directions for relatively changing a lightness component and a saturation component in the color space.

16. The color image processing method according to claim 11, wherein the color adjusting step includes being coordinated with the change in “brightness” as the sensuous term and causing the lightness component and the saturation component of the color image data to be relatively changed with the same positive or negative sign in response to the input of the instruction in the operation input step.

17. The color image processing method according to claim 11, wherein the color adjusting step includes being coordinated with the change in “deepness” as the sensuous term and causing the lightness component and the saturation component of the color image data to be relatively changed with opposite positive or negative sign in response to the input of the instruction in the operation input step.

18. The color image processing method according to claim 11, wherein a plurality of terms different from each other are defined as the sensuous terms, and the plurality of terms include a plurality of terms which signify opposite meanings in pairs.

19. The color image processing method according to claim 12, wherein the operation input step includes selecting any one of:
a first color adjusting mode for increasing the lightness component and increasing the saturation component;
a second color adjusting mode for decreasing the lightness component and decreasing the saturation component;
a third color adjusting mode for decreasing the lightness component and increasing the saturation component; and
a fourth color adjusting mode for increasing the lightness component and decreasing the saturation component,
wherein in the color adjusting step,
when the first color adjusting mode is selected in the operation input step, a relative change between the lightness component and the saturation component has a directional property that matches a sense given by a term “brighter” as the sensuous term,
when the second color adjusting mode is selected in the operation input step, a relative change between the lightness component and the saturation component has a directional property that matches a sense given by a term “darker” as the sensuous term,
when the third color adjusting mode is selected in the operation input step, a relative change between the lightness component and the saturation component has a directional property that matches a sense given by a term “deeper” as the sensuous term, and
when the fourth color adjusting mode is selected in the operation input step, a relative change between the lightness component and the saturation component has a directional property that matches a sense given by a term “paler” as the sensuous term.

20. The color image processing method according to claim 12, wherein the operation input step includes selecting any one of:
a first color adjusting mode for relatively increasing and decreasing the lightness component and the saturation component in the same direction; and
a second color adjusting mode for relatively increasing and decreasing the lightness component and the saturation component in opposite directions,
wherein, in the color adjusting mode, when the first color adjusting mode is selected in the operation input step, the relative change between the lightness component and the saturation component has a directional property that matches a sense given by the term “brighter” as the sensuous term, and
when the second color adjusting mode is selected in the operation input step, the relative change between the lightness component and the saturation component has a directional property that matches a sense given by the term “deeper” as the sensuous term.
